(19) United States
(12) Patent Application Publication
(10) Pub. No.: US 2010/0300877 A1
(43) Pub. Date: Dec. 2, 2010

(54) HIGH UTILIZATION ROTATABLE TARGET USING CERAMIC TITANIUM OXIDE RING

(75) Inventors: Steven J. Nadel, Berkeley, CA (US); James G. Rietzel, Antioch, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/476,936

(22) Filed: Jun. 2, 2009

(51) Int. Cl. C23C 14/06; B29C 65/48

(52) U.S. Cl. 204/298.13; 156/296

(57) ABSTRACT

A sputtering target assembly and its manufacturing method are provided for sputtering ceramic material on a substrate. The sputtering target assembly comprises a backing tube having a central portion, a first end and a second end; at least one cylindrical sputtering target member comprising a first ceramic material; and at least one collar comprising a second ceramic material different than the first ceramic material. The cylindrical sputtering target member is coupled to the backing tube at the central portion, and the collar is coupled to the backing tube at an area between one of the first and second ends and the cylindrical sputtering target member. In one embodiment, the sputtering rate of the collar is less than or equal to the sputtering rate of the cylindrical sputtering target member.

### BACKGROUND OF THE INVENTION

1. Field of the Invention

Embodiments disclosed herein generally relate to sputtering target assemblies and methods for making the same.

2. Description of the Related Art

Rotating magnetrons are becoming widely used for depositing thin films on substrates. Some of the products made by sputtering include semiconductor devices, compact discs (CD), hard disks, flat panel displays, solar panels, mirrors, architectural glass, etc.

A rotating magnetron generally comprises a target tube having the target material to be sputtered onto a substrate to be coated. There is a racetrack shaped magnetic structure disposed within the target tube for concentrating excited ions to bombard the sputtering target and sputter off atoms of the target material to be deposited on the substrate. The racetrack shaped magnet structure has turnaround portions near both ends of the target tube. Each of the turnaround portions has a relatively greater magnetic field strength than a central portion of the target tube, and a greater unit area at the target surface being influenced by the magnetic field, thus causing the target material of the target tube to sputter more rapidly near the turnaround portions. As a result, the end portions of the target tube near the turnaround portions will be worn out much more rapidly than the other portions of the target tube, and much of the central portion of the target tube will be wasted when the entire target tube has to be changed due to the worn-out of the end portions of the target tube.

One technique is used to solve the aforementioned problems by adding thicker material to the ends of the target tube. However, such conventional skill requires special modifications to cathode components which complicate operation of the cathode.

Another technique involves welding a titanium end ring at the end of the target tube. However, this solution is not applicable to ceramic targets. Sub-stoichiometric ceramic targets are increasingly being used for applications such as high index layers, for example TiO₂ and transparent conductors, for example Zn(Al)O. On the other hand, manufacturing and material costs for the ceramic targets are quite high.

Therefore, it is desirable to provide a sputtering target assembly with ceramic sputtering targets and its manufacturing method for increasing the utilization of the available ceramic sputtering material.

### SUMMARY OF THE INVENTION

According to one aspect of the invention, a sputtering target assembly comprises a backing tube, at least one cylindrical sputtering target member and at least one collar. The backing tube has a central portion, a first end, and a second end. The at least one cylindrical sputtering target member is coupled to the backing tube at the central portion. Each of the at least one cylindrical sputtering target members comprises a first ceramic material and has a first thickness. The at least one collar is coupled to the backing tube at an area between one of the first and second ends and the at least one cylindrical sputtering target member, and each of the at least one collars comprises a second ceramic material different than the first ceramic material.

In another aspect, the sputtering rate of the collar is less than or equal to the sputtering rate of the cylindrical sputtering target member.

In another aspect, the sputtering target assembly comprises a magnetic structure disposed within the backing tube. The magnetic structure has a turnaround portion near each of the first and second ends of the backing tube, wherein the collar is disposed over the turnaround portion.

In another aspect, a method for making the sputtering target assembly is provided. The method comprises coaxially stacking the at least one hollow cylindrical sputtering target onto a backing tube; coaxially stacking at least one hollow cylindrical collar respectively between at least one end of the backing tube and the at least one hollow cylindrical sputtering target; and coupling the at least one hollow cylindrical sputtering target and the at least one hollow cylindrical collar to the backing tube with an adhesive material. Each of the at least one cylindrical sputtering target members comprises the first ceramic material, and has a first thickness. Each of the at least one hollow cylindrical collars comprises a second ceramic material different than the first ceramic material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view showing a sputtering target system in accordance with one embodiment.

FIG. 2A is a schematic explosive view showing a sputtering target assembly in accordance with another embodiment.

FIG. 2B is a schematic assembled view showing the sputtering target assembly in accordance with another embodiment.

FIG. 2C is a schematic side view showing the sputtering target assembly in accordance with another embodiment.

FIG. 2D is a schematic cross-sectional diagram viewed along line A-A′ shown in FIG. 2C.

FIG. 2E is a schematic cross-sectional diagram viewed along line B-B′ shown in FIG. 2C.

FIG. 2F is a schematic side view showing the sputtering target assembly with a magnetic field in accordance with another embodiment.

FIG. 2G is a schematic view showing the magnetic field distributed along the sputtering target assembly in accordance with another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

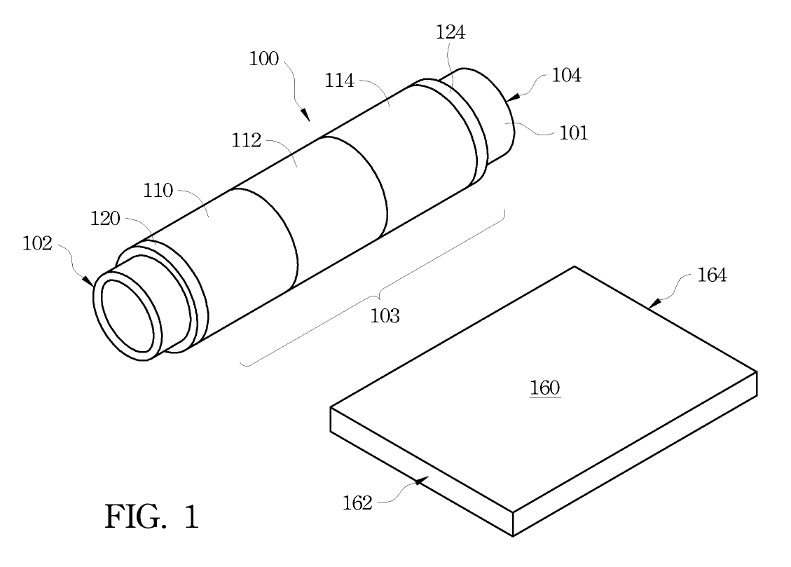

Embodiments disclosed herein are generally directed to using at least one collar comprising a second ceramic material as a universal target fixation for fixing at least one sputtering target member comprising a first ceramic material different than the second ceramic material, wherein the collar is bonded to a backing tube during a manufacturing process of the sputtering target member. The embodiments disclosed herein are particularly applicable to rotating magnetrons, but are not limited thereto. Referring to FIG. 1, FIG. 1 is a schematic view showing a sputtering target system in accordance with one embodiment. A sputtering target assembly 100 is disposed opposite a substrate 160 and beyond the edges 162 and 164 of the substrate 160. The length of the sputtering target assembly 100 is sufficient to provide the desired film uniformity over the length of the substrate 160.

The sputtering target assembly 100 comprises a backing tube 101, cylindrical sputtering target members 110, 112 and 114, and collars 120 and 124. The backing tube 101 has a central portion 103, a first end 102 and a second end 104. The cylindrical sputtering target members 110, 112 and 114 are coupled to the backing tube 101 at the central portion 103, and each of the cylindrical sputtering target members 110, 112 and 114 comprises a first ceramic material. In one embodiment, the first ceramic material is substantially identical for each of the cylindrical sputtering target members 110, 112 and 114. In another embodiment, the first ceramic material may be different for each of the cylindrical sputtering target members 110, 112 and 114. The collar 120 is coupled to the backing tube 101 at an area between the first end 102 and the cylindrical sputtering target member 110, and the collar 124 is coupled to the backing tube 101 at an area between the second end 104 and the cylindrical sputtering target member 114.

The location of each of the collars 120 and 124 is far enough beyond the length of the substrate 160, so that in the normal sputtering geometry (vertical separation between the tube and the substrate), the material sputtered from the collars 120 and 124 does not reach the edges 162 and 164 of the substrate 160 in quantities sufficient to affect the performance of the deposited films. In one embodiment, the backing tube 101 comprises stainless steel and the second ceramic material is a titanium-containing ceramic material. In another embodiment, the second ceramic material comprises titanium dioxide. In another embodiment, the first ceramic material can comprise indium-tin alloys, ceramics of indium oxide/tin oxide, zinc oxide or oxides of zinc doped with 0-10 wt % aluminum. However, the first and second ceramic materials can be any combinations of two ceramic materials as long as the sputtering rate of the second ceramic material is less than the sputtering rate of the first ceramic material. In this embodiment, the ratio of the sputtering rate of the first ceramic material to the sputtering rate of the second ceramic material is between about 2:1 to about 3:1.

In one embodiment, each of the cylindrical sputtering target members 110 and 114 has a first thickness, and each of the collars 120 and 124 has a second thickness, wherein the second thickness is substantially equal to the first thickness so as to provide fixations for the cylindrical sputtering target members 110, 112 and 114 on the backing tube 101. In another embodiment, each of the cylindrical sputtering target members 110, 112 and 114 has a first thickness. In another embodiment, the cylindrical sputtering target members 110, 112 and 114 and the collars 120 and 124 have the same inside and outside diameters so that the collars can be bonded to the backing tube 101 during a manufacturing process.

In one embodiment, two collars 120 and 124 are used as fixations for fixing the cylindrical sputtering target members 110, 112 and 114 on the backing tube 101. However, one collar (used as one fixation) with one target flange (used as the other fixation) disposed at one end of the backing tube is also applicable to the embodiments of the present invention.

In this embodiment, the sputtering target comprises a plurality of cylindrical sputtering target members 110, 112 and 114, which are particularly advantageous to manufacturing a long ceramic sputtering target. However, one single piece of cylindrical sputtering target member is also applicable to the embodiments of the present invention.

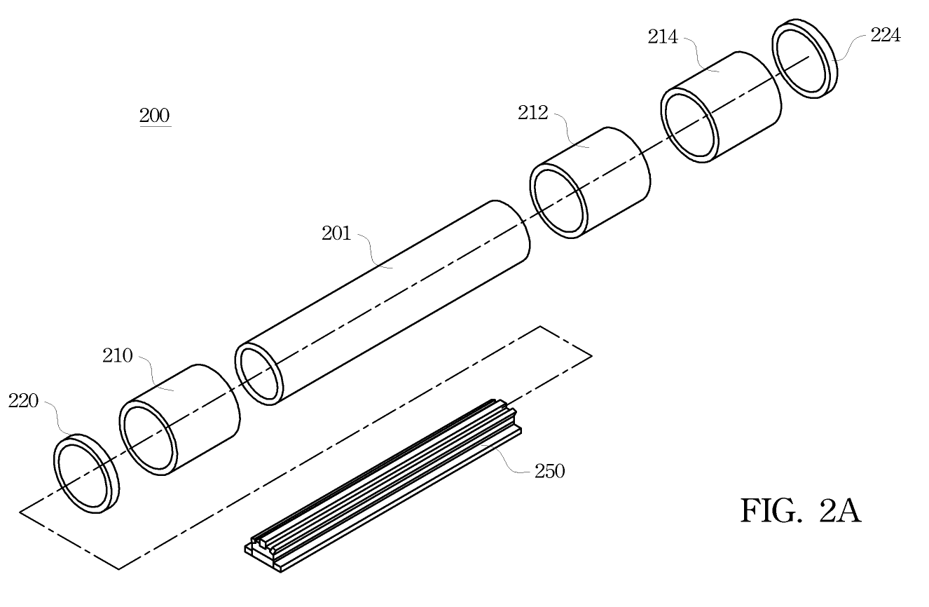

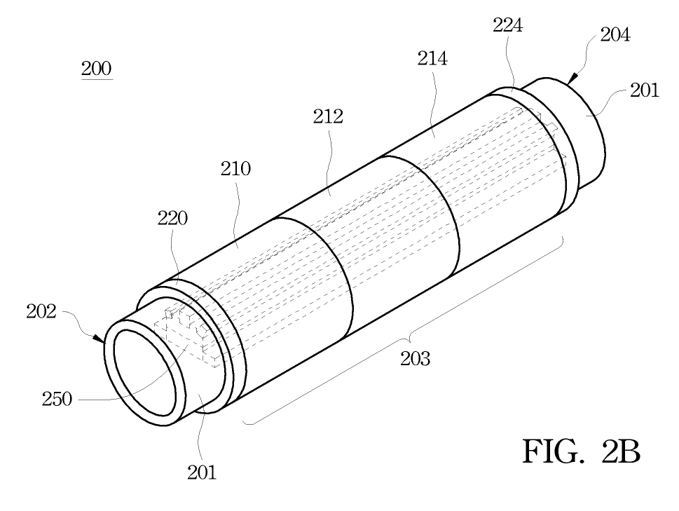

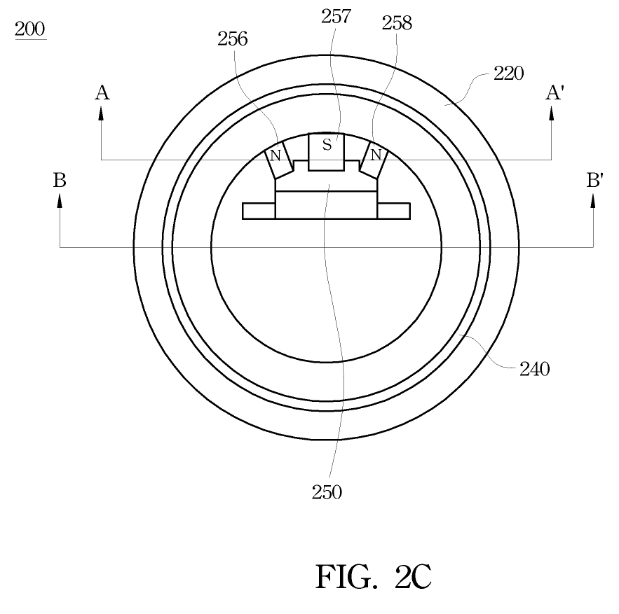

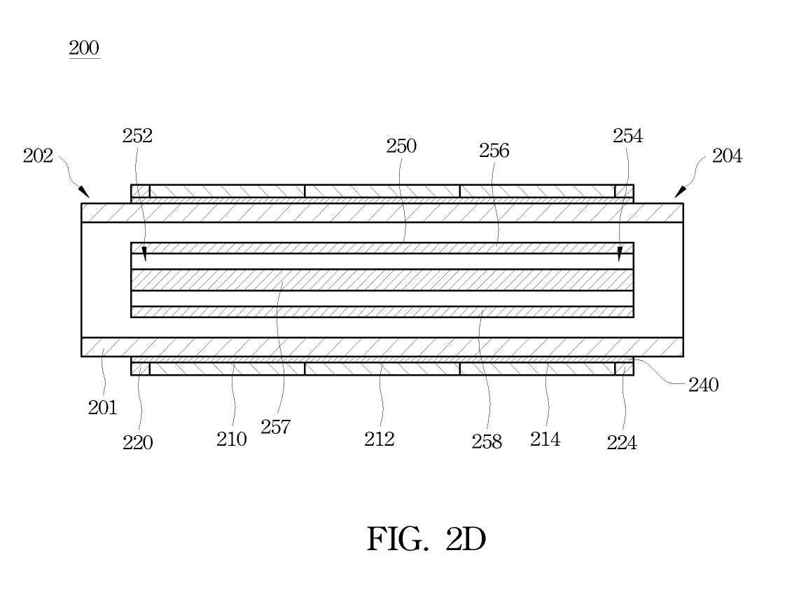

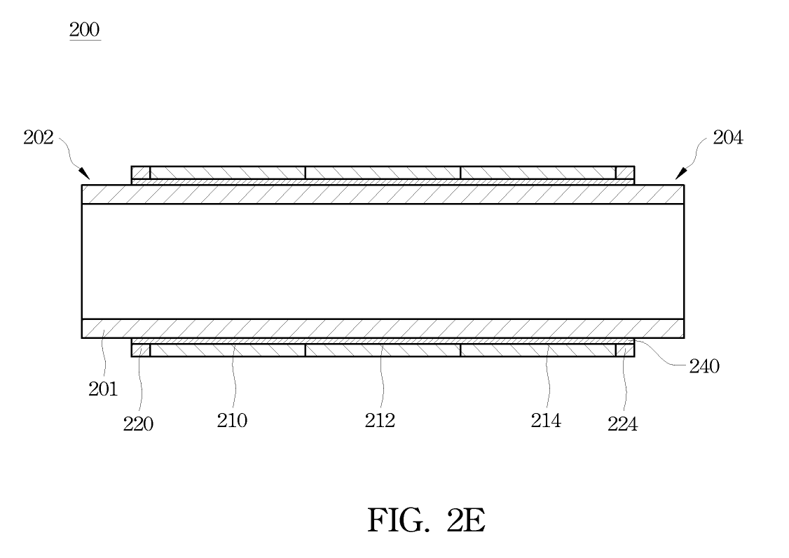

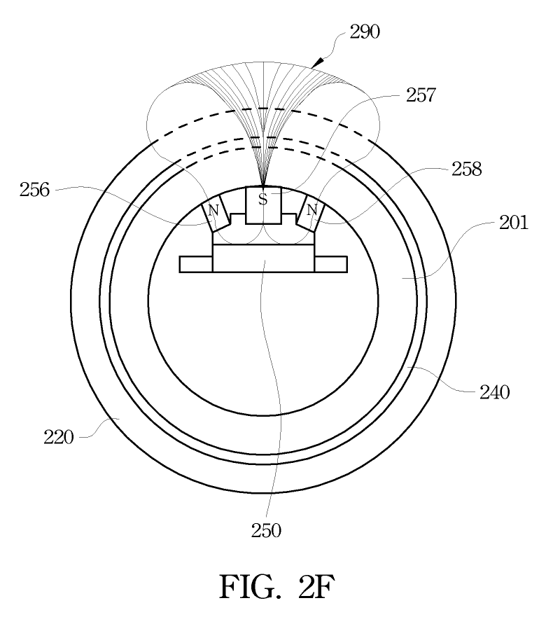

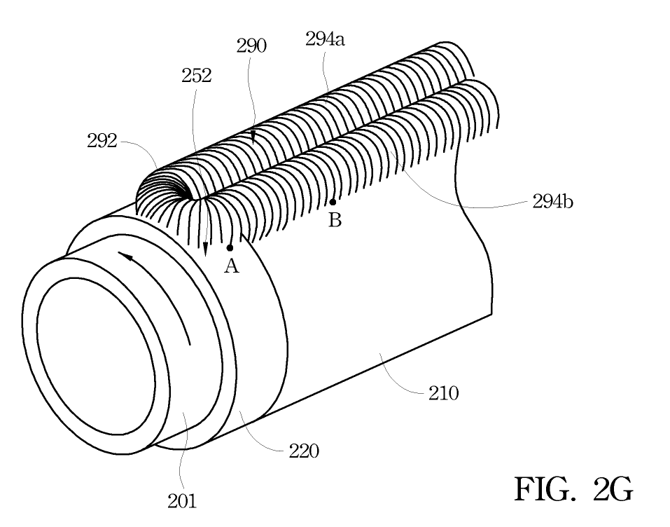

Referring to FIGS. 2A and 2B, FIGS. 2A and 2B are respective schematic explosive and assembled views showing a sputtering target assembly 200. The sputtering target assembly 200 comprises a backing tube 201, cylindrical sputtering target members 210, 212 and 214, collars 220 and 224, and a magnetic structure 250. The backing tube 201 has a central portion 203, a first end 202 and a second end 204. The cylindrical sputtering target members 210, 212 and 114 are coupled to the backing tube 201 at the central portion 203, and each of the cylindrical sputtering target members 210, 212 and 214 comprises the first ceramic material described above. The collar 220 is coupled to the backing tube 201 at an area between the first end 202 and the cylindrical sputtering target member 210, and the collar 224 is coupled to the backing tube 201 at an area between the second end 204 and the cylindrical sputtering target member 214. The magnetic structure 250 can be such as a racetrack shaped magnetic array, and is disposed within the backing tube 201 and extending from the collar 220 to the collar 224 for establishing a magnetic field traveling in a closed loop, commonly referred to as a “race track”, which establishes the path or region along which sputtering or erosion of the target material takes place.

Referring to FIGS. 2C, 2D and 2E, FIG. 2C is a schematic side view of the sputtering target assembly 200, and FIGS. 2D and 2E are schematic cross-sectional diagrams respectively viewed along line A-A′ and line B-B′ shown in FIG. 2C. The cylindrical sputtering target members 210, 212 and 214 and the collars 220 and 224 are coupled to the backing tube 201 with an adhesive material 240. The magnetic structure 250 comprises three alternating magnetic poles of the magnetic arrays 256, 257 and 258 arranged in straight parallel rows along the length of the backing tube 201. In one case, the poles of the magnetic arrays 256, 257 and 258 are arranged to have respective north, south and north polarities. In another case, an opposite configuration of respective south, north and south polarities may also be used. The magnetic structure 250 has a turnaround portion 252 near the first end 202 and a turnaround portion 254 near the second end 204 of the backing tube 201. The turnaround portions 252 and 254 generally cause high erosion regions on the sputtering target assembly, which will be described in more detail later. For overcoming this problem, the collar 220 is disposed over the turnaround portion 252, and the collar 224 is disposed over the turnaround portion 254. Hereinafter, the features of the magnetic structure 250 are described, especially for the turnaround portions 252 and 254.

Referring to FIGS. 2F and 2G, FIG. 2F is a schematic side view showing the sputtering target assembly 200 with a magnetic field; and FIG. 2G is a schematic view showing the magnetic field distributed along the sputtering target assembly 200, wherein only one half of the sputtering target assembly 200 are shown as an example for explanation, which is also applicable to the other half of the sputtering target assembly 200. As shown in FIG. 2F, the poles of the magnetic arrays 256, 257 and 258 of the magnetic structure 250 are positioned in relation to the backing tube 201 so as to generate a magnetic field 290 running from one pole, through the backing tube 201 up the collar 220, and back through the backing tube 201 in a curved path to an adjacent pole having an opposite polarity.

As shown in FIG. 2G, the poles of the magnetic arrays 256, 257 and 258 produce a racetrack magnetic field 290 for confining plasma (excited ions) on the sputtering target's surface to bombard the sputtering target and sputter off atoms of the target material to be deposited on the substrate. The racetrack magnetic field 290 consists of two straight sections 294a and 294b running longitudinally across the target surface; an end section 292 at the turnaround portion 252; and the other end section (not shown) at the turnaround portions 254 shown in FIG. 2D. The straight section 294a is generated from the top surfaces (N poles) of the magnetic array 256 to the top surfaces (S poles) of the magnetic array 257; the straight section 294b is generated from the top surfaces (N poles) of the magnetic array 258 to the top surfaces (S poles) of the magnetic array 257; and the end sections at the turnaround portions 252 and 254 are generated from the N poles to the S poles (not shown) of the magnetic array 256, from the N poles (not shown) to the S poles of the magnetic array 257 and from the N poles to the S poles (not shown) of the magnetic array 258. While the backing tube 201 is rotated against the magnetic structure 250, a point A at the collar 220 and a point B at the cylindrical sputtering target member 210 moves in parallel directions to cross over the end section 292 and the straight sections 294a and 294b respectively. The end section 292 is a continuous structure but the straight sections 294a and 294b are interrupted by a gap, and thus the point A at the collar 220 will be exposed to the active area of the plasma longer than the point B at the cylindrical sputtering target member 210, i.e., the points at the collars 220 and 224 will be exposed to the active area of the plasma longer than the points at the cylindrical sputtering target members 210, 212 and 214.

The longer exposure to the plasma generally causes the same material to sputter more rapidly. To compensate for the effect described above caused by the rotation through the turnaround portions 252 and 254, the magnetic field strength at each of the turnaround portions 252 and 254 would have to be significantly weaker than in the center of the magnetic structure 250. However, this solution of lowering the magnetic field strength at each of the turnaround portions 252 and 254 has run into another problem, generally referred to as the “cross corner” effect. The gradient in the magnetic field strength caused by making the magnetic fields at the turnaround portions 252 and 254 significantly weaker than the center of the magnetic structure 250 causes loss of electron confinement in the plasma as electrons enter this transition region, resulting in an area of higher plasma density in that region and thus a higher erosion. Consequently, there are two areas of higher deposition occurring at or near the entry of each turn around portion. In other words, the solution of lowering the magnetic field strength at each turnaround portion merely has displaced the region of higher erosion from a position outside of the substrate area (corresponding to the turn around portions 252 and 254) to the transition regions corresponding to the region on either side of the intersections of the collar 220/the cylindrical sputtering target member 210 and the collar 224/the cylindrical sputtering target member 214 in FIG. 2B. As a result, if the second ceramic material of the collar 220 and also of the collar 224 had the same property of sputtering rate as the first ceramic material of the cylindrical sputtering target members 210, 212 and 214, the second ceramic material of the collars 220 and 224 would be worn out well before the cylindrical sputtering target members 210, 212 and 214 have to be replaced, thus wasting much of the cylindrical sputtering target members 210, 212 and 214. Therefore, the embodiments of the present invention advantageously adopt the second ceramic material of which the property of sputtering rate is less than that of the first ceramic material, so that the collars 220 and 224 over the turnaround portions 252 and 254 can sputter at a rate less than or equal to the cylindrical sputtering target members 210, 212 and 214. In another embodiment, the second ceramic material is preferably selected to make the collars 220 and 224 (the second ceramic material) sputter at about the same rate as the cylindrical sputtering target members 210, 212 and 214 (the first ceramic material), so that the useful life of the collars 220 and 224 may end at about the same time as that of the cylindrical sputtering target members 210, 212 and 214 ends, thus saving the material cost of the first ceramic material.

On the other hand, the turn around portions 252 and 254 are designed to be outside the region of the substrate and this design moves the high erosion region of the sputtering target assembly closer to the substrate area. As such, in this high erosion region, the approach of using slower sputtering material as the second sputtering material is not feasible, because the material sputtered from this region reaches the substrate and if different in composition would contaminate and affect film properties. It also causes more non-uniformity in the deposited film, since the higher erosion region is more directly coupled to the edge of the substrate. Therefore, the location of each of the collars 220 and 224 may be far enough beyond the length of the substrate, so that in the normal sputtering geometry, the second ceramic material sputtered from the collars 220 and 224 does not reach the edges of the substrate in quantities sufficient to affect the performance of the deposited films, thereby keeping the second ceramic material in a position where it can be managed without affecting the coating to the substrate.

The following description is stated for explaining a method for making the sputtering target assembly 200 in accordance with the embodiments of the present invention. As shown in FIG. 2E, several hollow cylindrical sputtering targets comprising the first ceramic material are prepared as the cylindrical sputtering target members 210, 212 and 214, and two hollow cylindrical collars comprising the second ceramic material are prepared as the collars 220 and 224. Then, the hollow cylindrical sputtering targets 210, 212 and 214 are coaxially stacked onto the backing tube 201, and the hollow cylindrical collar 220 is coaxially stacked between the first end 102 of the backing tube 201, and the hollow cylindrical collar 224 is coaxially stacked between the first end 204 of the backing tube 201. Thereafter, the hollow cylindrical sputtering targets 210, 212 and 214 and the hollow cylindrical collars 220 and 224 are coupled to the backing tube 201 with an adhesive material 240. The adhesive material 240 can be first applied on the outer surface of the backing tube 201 before the hollow cylindrical sputtering targets 210, 212 and 214 and the hollow cylindrical collars 220 and 224 are positioned on the backing tube 201; or can be filled into the gaps between every two adjacent hollow cylindrical sputtering targets 210, 212 and 214, and the gaps between the hollow cylindrical collars 220/224 and the hollow cylindrical sputtering targets 210/214. Since the hollow cylindrical collars 220 and 224 can be manufactured and coupled to the backing tube 201 in the same fashion as the hollow cylindrical sputtering targets 210, 212 and 214, the applications of the foregoing embodiments only require minimal modification to the existing ceramic target manufacturing process, and no modification to other existing cathode components, assemblies or operating procedures, thus having low cost impact for resolving the aforementioned problems caused by the high magnetic filed intensity at the turnaround portions.

According to the foregoing embodiments, at least one collar comprising a second ceramic material is coupled to a backing tube at an area between one of the first and second ends of the backing tube and at least one cylindrical sputtering target member comprising a first ceramic material, wherein the collar is disposed over a turnaround portion of a magnetic structure disposed within the backing tube, and the sputtering rate of the second ceramic material is less than that of the first ceramic material, thereby having the sputtering rate of the collar be less than or equal to that of the cylindrical sputtering target member, thus saving the material cost of the cylindrical sputtering target member. Moreover, the at least one collar can be manufactured and coupled to the backing tube in the same fashion as the at least one cylindrical sputtering target member, thus having low cost impact for resolving the erosion problems.

While the foregoing is directed to embodiments of the present invention, other and further embodiments of the invention may be devised without departing from the basic scope thereof, and the scope thereof is determined by the claims that follow.

1. A sputtering target assembly, comprising:
a backing tube having a central portion, a first end and a second end;
at least one cylindrical sputtering target member coupled to the backing tube at the central portion, each of the at least one cylindrical sputtering target members having a first ceramic material and a first thickness; and
at least one collar coupled to the backing tube at an area between one of the first and second ends and the at least one cylindrical sputtering target member, each of the at least one collar comprising a second ceramic material different than the first ceramic material.

2. The sputtering target assembly of claim 1, wherein the sputtering rate of the at least one collar is less than or equal to the sputtering rate of the at least one cylindrical sputtering target member.

3. The sputtering target assembly of claim 1, wherein the second ceramic material is a titanium-containing ceramic material.

4. The sputtering target assembly of claim 3, wherein the second ceramic material is titanium dioxide.

5. The sputtering target assembly of claim 1, wherein the ratio of the sputtering rate of the first ceramic material to the sputtering rate of the second ceramic material is about 2:1 to about 3:1.

6. The sputtering target assembly of claim 1, wherein the backing tube comprises stainless steel.

7. The sputtering target assembly of claim 1, wherein the at least one cylindrical sputtering target member and the at least one collar have the same inside and outside diameters.

8. The sputtering target assembly of claim 1, comprising:
a magnetic structure disposed within the backing tube, the magnetic structure having a turnaround portion near each of the first and second ends of the backing tube, wherein the collar is disposed over the turnaround portion.

9. A method for making a sputtering target assembly, comprising:
coaxially stacking at least one hollow cylindrical sputtering target onto a backing tube, each of the at least one hollow cylindrical sputtering target comprising a first ceramic material;
coaxially stacking at least one hollow cylindrical collar respectively between at least one end of the backing tube and the at least one hollow cylindrical sputtering target, each of the at least one hollow cylindrical collars having a second ceramic material different than the first ceramic material; and
coupling the at least one hollow cylindrical sputtering target and the at least one hollow cylindrical collar to the backing tube with an adhesive material.

10. The method of claim 9, wherein the second ceramic material is a titanium-containing ceramic material.

11. The method of claim 10, wherein the second ceramic material is titanium oxide.

12. The method of claim 9, wherein the ratio of the sputtering rate of the first ceramic material to the sputtering rate of the second ceramic material is ranged from about 2:1 to about 3:1.

13. The method of claim 9, wherein the backing tube comprises stainless steel.

14. The method of claim 9, wherein the at least one hollow cylindrical sputtering target and the hollow cylindrical collar have the same inside and outside diameters.

15. A sputtering target assembly, comprising:
a backing tube having a central portion, a first end and a second end;
a magnetic structure disposed within the backing tube, the magnetic structure having a turnaround portion near each of the first and second ends of the backing tube;
at least one cylindrical sputtering target member coupled to the backing tube at the central portion, each of the at least one cylindrical sputtering target members having a first ceramic material and a first thickness; and
at least one collar coupled to the backing tube at an area between one of the first and second ends and the at least one cylindrical sputtering target member, each of the at least one collar comprising a second ceramic material different than the first ceramic material, wherein the collar is disposed over the turnaround portion, and the sputtering rate of the at least one collar is less than or equal to the sputtering rate of the at least one cylindrical sputtering target member.

16. The sputtering target assembly of claim 15, wherein the second ceramic material is a titanium-containing ceramic material.

17. The sputtering target assembly of claim 16, wherein the second ceramic material is titanium dioxide.

18. The sputtering target assembly of claim 15, wherein the ratio of the sputtering rate of the first ceramic material to the sputtering rate of the second ceramic material is about 2:1 to about 3:1.

19. The sputtering target assembly of claim 15, wherein the backing tube comprises stainless steel.

20. The sputtering target assembly of claim 15, wherein the at least one cylindrical sputtering target member and the at least one collar have the same inside and outside diameters.
